(19) United States
(12) Patent Application Publication
(10) Pub. No.: US 2026/0198679 A1
(43) Pub. Date: Jul. 16, 2026

(54) SUBSTRATE PROCESSING SYSTEM AND MOVABLE MAINTENANCE APPARATUS

(71) Applicant: Tokyo Electron Limited, Tokyo (JP)

(72) Inventor: Norihiko AMIKURA, Miyagi (JP)

(73) Assignee: Tokyo Electron Limited, Tokyo (JP)

(21) Appl. No.: 19/557,182

(22) Filed: Mar. 5, 2026

Related U.S. Application Data
(63) Continuation of application No. PCT/JP2024/031455, filed on Sep. 2, 2024.

(30) Foreign Application Priority Data
Sep. 14, 2023 (JP) 2023-149475

(51) Int. Cl. A46B 13/02; A46B 5/00; A46B 5/06; A46B 15/00; B65G 54/02; H10P 72/00; H10P 72/30

(52) U.S. Cl. CPC A46B 13/02; A46B 5/0004; A46B 5/06; A46B 15/0006; B65G 54/02; H10P 72/0464; H10P 72/3204; A46B 2200/3073

(57) ABSTRACT

A substrate processing system includes: a substrate processing apparatus; a maintenance apparatus; and control circuitry. The substrate processing apparatus includes a substrate processing module, and a vacuum transfer module. The vacuum transfer module includes a vacuum transfer chamber and a first planar motor to move at least one magnetically floating movable body along a first plane in the vacuum transfer chamber. The maintenance apparatus includes a standby chamber connected to the vacuum transfer chamber, and a second planar motor to move the at least one magnetically floating movable body along a second plane extending from the first plane into the standby chamber, and the control circuitry controls the first planar motor and the second planar motor to replace an operating magnetically floating movable body with a replacement magnetically floating movable body located in the standby chamber.

### CROSS-REFERENCE TO RELATED APPLICATIONS

This application is a bypass continuation application of international application No. PCT/JP2024/031455 having an international filing date of Sep. 2, 2024, and designating the United States, the international application being based upon and claiming the benefit of priority from Japanese Patent Application No. 2023-149475, filed on Sep. 14, 2023, the entire contents of each are incorporated herein by reference.

### TECHNICAL FIELD

The present disclosure relates to a substrate processing system and a movable maintenance apparatus.

### BACKGROUND

Patent Literature 1 discloses a substrate processing system including a plurality of chambers, a transfer chamber connecting the chambers, and a substrate transfer device provided in the transfer chamber. The substrate transfer device is provided in the transfer chamber, and includes a planar motor having arranged coils, a transfer unit that moves on the planar motor, and a controller that controls energization of the coils. The transfer unit includes a first base that has arranged first magnets and moves on the planar motor, a second base that has a second magnet and moves on the planar motor and is coaxially disposed with the first base, and an arm that extends and retracts by rotating the second base with respect to the first base.

Patent Literature 2 discloses a transfer chamber that includes a first opening communicating with an adjacent chamber, a planar motor having arranged coils, a movable body having a valve body that moves on the planar motor and closes the first opening, and a controller that controls the energization of the coils.

### CITATION LIST

### Patent Documents

Patent Literature 1: JP2022-133867A

Patent Literature 2: JP2022-143380A

### SUMMARY

According to the technique of the present disclosure, maintenance of a substrate processing apparatus having a magnetically floating vacuum transfer chamber is performed without being exposed to an atmosphere.
(1) An aspect of the present disclosure is a substrate processing system including: a substrate processing apparatus; a maintenance apparatus; and control circuitry. The substrate processing apparatus includes a substrate processing module including a substrate processing chamber, and a vacuum transfer module. The vacuum transfer module includes a vacuum transfer chamber having a first opening and a second opening, the vacuum transfer module being connected to the substrate processing module through the first opening, and a first planar motor configured to move at least one magnetically floating movable body along a first plane in the vacuum transfer chamber. The maintenance apparatus includes a standby chamber connected to the vacuum transfer chamber through the second opening, and a second planar motor configured to move the at least one magnetically floating movable body along a second plane extending from the first plane into the standby chamber, and the control apparatus is configured to control the first planar motor and the second planar motor to replace an operating magnetically floating movable body of the at least one magnetically floating movable body located in the vacuum transfer chamber with a replacement magnetically floating movable body of the at least one magnetically floating movable body located in the standby chamber.
(2) The substrate processing system according to (1), wherein
   the at least one magnetically floating movable body includes a magnetically floating substrate transferer configured to transfer a substrate within the vacuum transfer chamber.
(3) The substrate processing system according to (1), wherein
   the at least one magnetically floating movable body includes a magnetically floating gate valve configured to open and close the first opening.
(4) The substrate processing system according to (1), wherein
   the at least one magnetically floating movable body includes at least one magnetically floating maintenance unit that stands by in the standby chamber in a substrate processing mode, and
   the at least one magnetically floating maintenance unit includes at least one of a pick and a base.
(5) The substrate processing system according to (4), wherein
   the at least one magnetically floating maintenance unit includes a magnetically floating cleaning unit configured to clean the vacuum transfer chamber, and
   the magnetically floating cleaning unit includes a base; and plate brushes connected to the base of the magnetically floating cleaning unit.
(6) The substrate processing system according to 4, wherein
   the at least one magnetically floating maintenance unit further includes a magnetically floating retrieval unit configured to retrieve a movable body in the vacuum transfer chamber to the standby chamber, and
   the magnetically floating retrieval unit includes the pick and the base.
(7) The substrate processing system according to (4), wherein
   the at least one magnetically floating maintenance unit includes a magnetically floating monitoring unit configured to monitor an internal condition of the vacuum transfer chamber and the substrate processing module, and
   the magnetically floating monitoring unit includes an imager having a plate-shaped support member.
(8) The substrate processing system according to (1), wherein
   the maintenance apparatus is movable, and the standby chamber is detachably connected to the vacuum transfer chamber.
(9) A substrate processing system comprising:
   a substrate processing apparatus;
   a maintenance apparatus; and
   control circuitry, wherein
   the substrate processing apparatus includes
      a substrate processing module including a substrate processing chamber, and
      a vacuum transfer module,
      the vacuum transfer module includes
         a vacuum transfer chamber having a first opening and a second opening, the vacuum transfer chamber being connected to the substrate processing module through the first opening, and
         a first planar motor configured to move at least one magnetically floating movable body along a first plane in the vacuum transfer chamber,
   the maintenance apparatus includes
      a standby chamber connected to the vacuum transfer chamber through the second opening, and
      a second planar motor configured to move the at least one magnetically floating movable body along a second plane extending from the first plane into the standby chamber,
      the at least one magnetically floating movable body includes at least one magnetically floating maintenance unit standing by in the standby chamber in a substrate processing mode, the at least one magnetically floating maintenance unit including at least one of a pick and a base, and
   the control circuitry is configured to control the first planar motor and the second planar motor in a maintenance mode to move the at least one magnetically floating maintenance unit from the standby chamber to the vacuum transfer chamber.
(10) The substrate processing system according to (9), wherein
   the at least one magnetically floating maintenance unit includes a magnetically floating cleaning unit configured to clean the vacuum transfer chamber, and
   the magnetically floating cleaning unit includes a base; and plate brushes connected to the base of the magnetically floating cleaning unit.
(11) The substrate processing system according to (9), wherein
   the at least one magnetically floating maintenance unit further includes a magnetically floating retrieval unit configured to retrieve a movable body in the vacuum transfer chamber to the standby chamber, and
   the magnetically floating retrieval unit includes the pick and the base.
(12) The substrate processing system according to (11), wherein
   the magnetically floating retrieval unit includes a plurality of permanent magnets arranged in the base.
(13) The substrate processing system according to (9), wherein
   the at least one magnetically floating maintenance unit includes a magnetically floating monitoring unit configured to monitor an internal condition of the vacuum transfer chamber and the substrate processing module, and
   the magnetically floating monitoring unit includes an imager having a plate-shaped support member.
(14) The substrate processing system according to (9), wherein
   the maintenance apparatus is movable, and the standby chamber is detachably connected to the vacuum transfer chamber.
(15) The substrate processing system according to (9), wherein the at least one magnetically floating maintenance unit includes the pick attached to the base.
(16) A movable maintenance apparatus comprising:
   a standby chamber detachably connected to a vacuum transfer chamber; and
   a planar motor configured to move at least one magnetically floating movable body along a first plane in the standby chamber, the first plane extending from a second plane in the vacuum transfer chamber when the standby chamber is connected to the vacuum transfer chamber.
(17) The movable maintenance apparatus according to (16), wherein
   the at least one magnetically floating movable body includes at least one magnetically floating maintenance unit standing by in the standby chamber in a substrate processing mode, and
   the at least one magnetically floating maintenance unit includes at least one of a pick and a base.
(18) The movable maintenance apparatus according to (17), wherein
   the at least one magnetically floating maintenance unit includes a magnetically floating cleaning unit configured to clean the vacuum transfer chamber in a maintenance mode, and
   the magnetically floating cleaning unit includes a base; and plate brushes connected to the base of the magnetically floating cleaning unit.
(19) The movable maintenance apparatus according to (17), wherein
   the at least one magnetically floating maintenance unit further includes a magnetically floating retrieval unit configured to retrieve a movable body in the vacuum transfer chamber to the standby chamber in a maintenance mode, and
   the magnetically floating retrieval unit includes the pick and the base.
(20) The movable maintenance apparatus according to (17), wherein
   the at least one magnetically floating maintenance unit includes a magnetically floating monitoring unit configured to monitor an internal condition of the vacuum transfer chamber and a substrate processing module in a maintenance mode, and
   the magnetically floating monitoring unit includes an imager having a plate-shaped support member.

According to the present disclosure, maintenance of a substrate processing apparatus having a magnetically floating vacuum transfer chamber can be performed without being exposed to an atmosphere.

### BRIEF DESCRIPTION OF DRAWINGS

FIG. 1 is a system configuration diagram illustrating an example of a substrate processing system according to the present embodiment.

FIG. 2 is a plan view illustrating a schematic configuration of a substrate processing apparatus provided in the substrate processing system of FIG. 1.

FIG. 3 is a perspective view illustrating a schematic configuration of a magnetically floating substrate transfer unit provided in the substrate processing apparatus of FIG. 2.

FIG. 4 is a diagram illustrating a driving principle of the magnetically floating substrate transfer unit.

FIG. 5 is a perspective view illustrating a schematic configuration of a magnetically floating gate valve provided in the substrate processing apparatus of FIG. 2.

FIG. 6 is a plan view illustrating a schematic configuration of a maintenance apparatus provided in the substrate processing system of FIG. 1.

FIG. 7 is a vertical sectional view illustrating a schematic configuration of the maintenance apparatus provided in the substrate processing system of FIG. 1.

FIG. 8 is a plan view illustrating another example of the maintenance apparatus.

FIG. 9 is a system configuration diagram illustrating an example of a substrate processing system according to another embodiment.

FIG. 10 is a plan view illustrating a schematic configuration of the maintenance apparatus provided in the substrate processing system of FIG. 9.

FIG. 11 is a plan view illustrating another example of the maintenance apparatus.

FIG. 12 is a perspective view illustrating a schematic configuration of the magnetically floating cleaning unit accommodated in the maintenance apparatus of FIG. 11.

FIG. 13 is a plan view illustrating another example of the maintenance apparatus.

FIG. 14 is a side view illustrating an example of a support member of a magnetically floating monitoring unit.

FIG. 15 is a plan view illustrating another example of the maintenance apparatus.

### DETAILED DESCRIPTION

In a manufacturing process of a semiconductor device or the like, various processing such as film formation processing and etching processing are performed on a substrate such as a semiconductor wafer (hereinafter, referred to as a “wafer”) in a vacuum atmosphere (in a decompressed atmosphere). These types of processing are performed in a substrate processing apparatus.

The substrate processing apparatus includes a substrate processing chamber in which an inner portion is decompressed to perform the processing described above with respect to a substrate, and a vacuum transfer chamber in which a substrate transfer unit in which an inner portion is decompressed to transfer a substrate between the substrate processing chamber and another substrate processing chamber is provided. In one embodiment, a vacuum transfer module is implemented to transfer a substrate under a decompressed or vacuum atmosphere, and includes a vacuum transfer chamber and a substrate transfer unit disposed in the vacuum transfer chamber.

A magnetically floating substrate transfer unit may be used as the substrate transfer unit in the vacuum transfer chamber. The magnetically floating substrate transfer unit is implemented to move on a planar motor having arranged coils, and has a support that supports the substrate.

The substrate processing apparatus includes a gate valve that opens and closes an opening through which the substrate processing chamber and the vacuum transfer chamber communicate with each other. A magnetically floating gate valve may be used as the gate valve. Similar to the magnetically floating substrate transfer unit, the magnetically floating gate valve is implemented to move on the planar motor. However, unlike the substrate transfer unit, the magnetically floating gate valve has a valve body that closes an opening. The valve body of the magnetically floating gate valve is provided with a sealing member for sealing when the opening is closed.

Since the above-described magnetically floating substrate transfer unit transfers the processed substrate as well, a contact surface with the substrate becomes dirty, so that the cleaning is required.

Since the magnetically floating gate valve is contaminated by processing with respect to the substrate, the cleaning is required, and further, since the sealing member is consumed, it is necessary to replace the gate valve.

The cleaning of a magnetically floating unit such as the magnetically floating substrate transfer unit described above, that is, a magnetically floating movable body, and the replacement of the sealing member are performed, for example, by an operator replacing the entire magnetically floating unit with an unused unit. For this replacement by the operator, it is necessary to expose the vacuum transfer chamber to the atmosphere. However, when the chamber is exposed to the atmosphere, it takes a long time to return the vacuum transfer chamber to a state before the vacuum transfer chamber is exposed to the atmosphere after the replacement, so that productivity may be deteriorated.

Similarly, when the chamber is exposed to the atmosphere for the maintenance of the vacuum transfer chamber other than the replacement of the magnetically floating movable body of the vacuum transfer chamber, the productivity may be deteriorated.

Therefore, in the technique according to the present disclosure, the maintenance of the substrate processing apparatus including the vacuum transfer chamber in which the magnetically floating movable body is implemented to be movable, that is, the magnetically floating vacuum transfer chamber, is performed without being exposed to the atmosphere.

Hereinafter, a substrate processing system and a maintenance apparatus according to the present embodiment will be described with reference to the drawings. Like reference numerals will be given to like parts having substantially the same functions throughout the specification and the drawings, and redundant description thereof will be omitted.

### Substrate Processing System

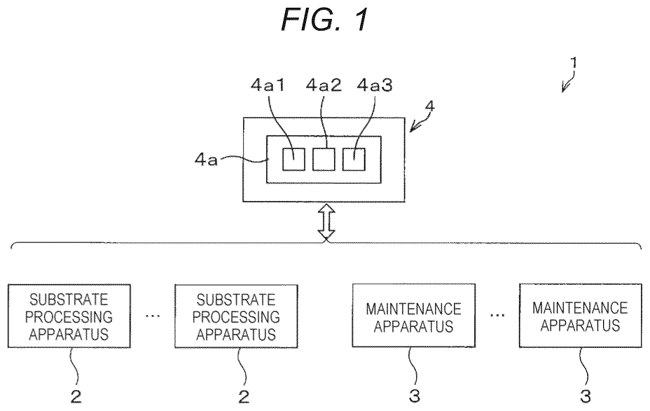

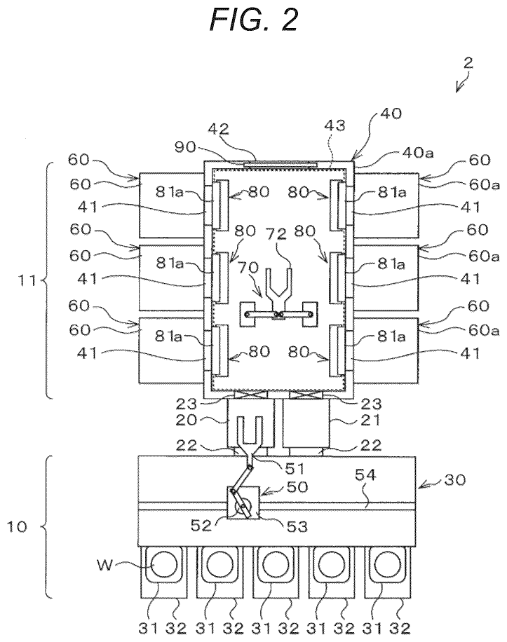

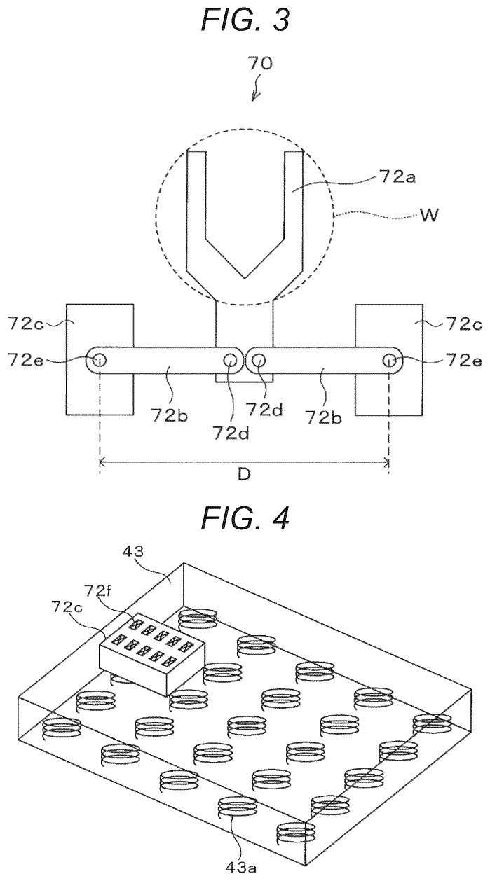

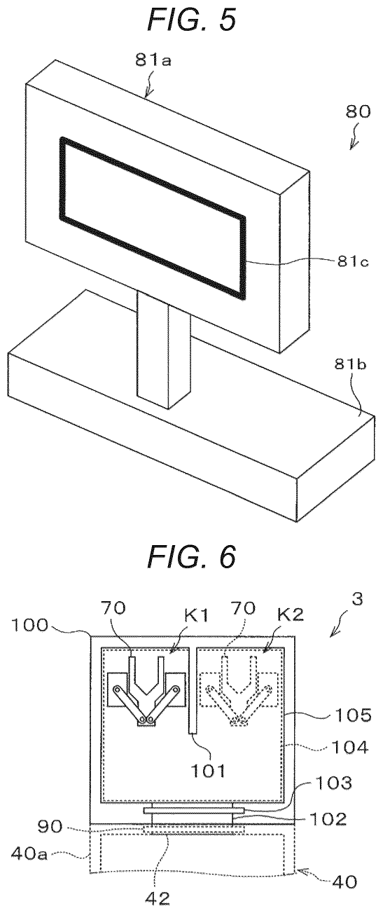

FIG. 1 is a system configuration diagram illustrating an example of a substrate processing system according to the present embodiment. FIG. 2 is a plan view illustrating a schematic configuration of a substrate processing apparatus provided in the substrate processing system of FIG. 1. FIG. 3 is a perspective view illustrating a schematic configuration of the substrate transfer unit provided in the substrate processing apparatus of FIG. 2. FIG. 4 is a view illustrating a driving principle of a substrate transfer unit. FIG. 5 is a perspective view illustrating a schematic diagram of a gate valve provided in the substrate processing apparatus of FIG. 2.

A substrate processing system 1 of FIG. 1 includes a plurality of substrate processing apparatuses 2, a plurality of maintenance apparatuses 3, and a control apparatus 4. The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium, such as a CD-ROM or DVD, and/or the memory of a FPGA or ASIC.

In each of the substrate processing apparatuses 2, for example, a substrate W is subjected to processing including desired gas processing such as film formation processing, cleaning processing, and other plasma processing.

As illustrated in FIG. 2, the substrate processing apparatus 2 has a configuration in which an atmospheric unit 10 and a decompression unit 11 are integrally connected to each other through load-lock modules 20 and 21. The atmospheric unit 10 includes an atmospheric module for performing desired processing on the substrate W under an atmospheric pressure atmosphere. The decompression unit 11 includes a decompression module which performs desired processing on the substrate W in a decompressed atmosphere.

The load-lock modules 20 and 21 are connected to an atmospheric transfer module 30 to be described later of the atmospheric unit 10 and a vacuum transfer module 40 to be described later of the decompression unit 11 via gate valves 22 and 23, respectively. The load-lock modules 20 and 21 are implemented to temporarily hold the substrate W. Each of the load-lock modules 20 and 21 is implemented such that an inner portion thereof can be switched between an atmospheric pressure atmosphere and a decompressed atmosphere (vacuum atmosphere).

The atmospheric unit 10 has the atmospheric transfer module 30 provided with a substrate transfer mechanism 50 to be described later, and a load port 32 on which a hoop 31 capable of storing a plurality of substrates W is placed. An orienter module (not illustrated) that adjusts an orientation of the substrate W in a horizontal direction, a storage module (not illustrated) that stores the substrates W, and the like may be provided adjacent to the atmospheric transfer module 30.

The atmospheric transfer module 30 includes a substantially rectangular parallelepiped-shaped housing, and an inside of the housing is maintained in an atmospheric pressure atmosphere. A plurality of load ports 32, for example, five load ports 32, are disposed side by side on one side surface forming a long side of the housing of the atmospheric transfer module 30. The load-lock modules 20 and 21 are disposed side by side on the other side surface forming the long side of the housing of the atmospheric transfer module 30.

The substrate transfer mechanism 50 that transfers the substrate W is provided inside the atmospheric transfer module 30. The substrate transfer mechanism 50 includes a transfer arm 51 that holds and moves the substrate W, a rotation base 52 that rotatably supports the transfer arm 51, and a rotation stage 53 on which the rotation base 52 is placed. A guide rail 54 extending in the longitudinal direction of the atmospheric transfer module 30 is provided inside the atmospheric transfer module 30. The rotation stage 53 is provided on the guide rail 54, and the substrate transfer mechanism 50 is implemented to be movable along the guide rail 54.

The decompression unit 11 includes the vacuum transfer module 40 and a substrate processing module 60. The vacuum transfer module 40 is provided adjacent to the substrate processing module 60, and transfers the substrate W in the vacuum atmosphere. The substrate processing module 60 performs processing such as film formation processing on the substrate W in the vacuum atmosphere.

A plurality of substrate processing modules 60 are connected to one vacuum transfer module 40. In the example illustrated in FIG. 2, six substrate processing modules 60 are connected. However, the present disclosure is not limited thereto, and fewer or more than six substrate processing modules 60 may be connected.

The vacuum transfer module 40 includes a vacuum transfer chamber 40a, and the substrate processing module 60 includes a substrate processing chamber 60a. The vacuum transfer chamber 40a and the substrate processing chamber 60a are implemented such that the inside thereof can be maintained in the decompressed atmosphere (vacuum atmosphere).

The vacuum transfer chamber 40a is connected to the load-lock modules 20 and 21. In one embodiment, the vacuum transfer module 40 transfers the substrate W transferred into the load-lock module 20 to one substrate processing module 60, and transfers the substrate W to the load-lock module 21 after being subjected to desired substrate processing.

The vacuum transfer chamber 40a has a first opening 41 and a second opening 42.

The vacuum transfer chamber 40a is connected to the substrate processing module 60 through the first opening 41. Specifically, the vacuum transfer chamber 40a is connected to the substrate processing chamber 60a. The first opening 41 allows an interior space of the vacuum transfer chamber 40a and an interior space of the substrate processing chamber 60a to communicate with each other.

The second opening 42 allows an interior space of the vacuum transfer chamber 40a and an outside of the substrate processing apparatus 2 to communicate with each other. For example, the vacuum transfer chamber 40a is connected to the maintenance apparatus 3 through the second opening 42 to be described later, specifically, connected to a standby chamber to be described later. In this case, the second opening 42 allows the interior space of the vacuum transfer chamber 40a and the interior space of the standby chamber to communicate with each other.

The vacuum transfer chamber 40a includes a planar motor 43 serving as a first planar motor. In one embodiment, the vacuum transfer chamber 40a includes a magnetically floating substrate transfer unit 70 and a magnetically floating gate valve 80 as a magnetically floating movable body. The vacuum transfer chamber 40a is provided with a gate valve 90.

The planar motor 43 is implemented to move at least one magnetically floating movable body along a bottom surface serving as a first plane in the vacuum transfer chamber 40a. In the present example, the planar motor 43 is provided on the bottom surface of the vacuum transfer chamber 40a, and is implemented to move the magnetically floating substrate transfer unit 70 and the magnetically floating gate valve 80 along the bottom surface.

The magnetically floating substrate transfer unit 70 (hereinafter, sometimes referred to as a “transfer unit 70”) supports and transfers the substrate W.

The magnetically floating gate valve 80 (hereinafter, sometimes referred to as the “gate valve 80”) opens and closes the first opening 41.

The gate valve 90 opens and closes the second opening 42.

As illustrated in FIG. 3, the transfer unit 70 includes an end effector 72a, two links 72b, and two bases 72c. The end effector 72a holds the substrate W. Each of the links 72b connects the end effector 72a and the base 72c. One end portion of the link 72b is connected to the end effector 72a to be rotatable around a rotation axis 72d in a vertical direction. The other end portion of the link 72b is connected to the base 72c to be rotatable around a rotation axis 72e in the vertical direction. The two links 72b can be advanced and retreated while maintaining the orientation of the end effector 72a by changing a distance D between the two rotation axes 72e (the two bases 72c). As illustrated in FIG. 4, a plurality of permanent magnets 72f are arranged in the base 72c. The base 72c moves on the planar motor 43 by a magnetic field generated by coils 43a to be described later of the planar motor 43.

A plurality of coils 43a are arranged in the planar motor 43. The coils 43a generate a magnetic field by being supplied with a current. The energization of the coils 43a is controlled by the control apparatus 4.

With such a configuration, the control apparatus 4 controls the energization (specifically, a current value) of each of the coils 43a of the planar motor 43 to control a position, an orientation, and a floating amount of the base 72c.

The control apparatus 4 can move or pivot the transfer unit 70 by, for example, controlling the energization of each of the coils 43a of the planar motor 43 such that the position of the base 72c is a desired position. That is, the control apparatus 4 can move the substrate W held by the end effector 72a of the transfer unit 70 by, for example, controlling the energization of the coils 43a of the planar motor 43.

Further, in the vacuum transfer chamber 40a, the substrate W held in the load-lock module 20 is received by the end effector 72a and transferred to the desired substrate processing module 60 (specifically, the substrate processing chamber 60a). The substrate W subjected to the desired substrate processing in the substrate processing module 60 is held by the end effector 72a and transferred to the load-lock module 21.

As illustrated in FIG. 5, the gate valve 80 has a valve body 81a and a base 81b. The valve body 81a is a member that closes the first opening 41, and is formed to be larger than the first opening 41 and smaller than the second opening 42. The valve body 81a is provided with a sealing member 81c that seals the portion where the first opening 41 is closed by the valve body 81a. The sealing member 81c is, for example, an O-ring. The valve body 81a is connected to the base 81b. Similar to the base 72c, a plurality of permanent magnets (not illustrated) are arranged in the base 81b. The base 81b moves on the planar motor 43 by the magnetic field generated by the coils 43a of the planar motor 43.

With such a configuration, the control apparatus 4 controls the energization (specifically, a current value) of each of the coils 43a of the planar motor 43 to control a position, an orientation, and a floating amount of the base 81b.

The control apparatus 4 can move or pivot the gate valve 80 by, for example, controlling the energization of each of the coils 43a of the planar motor 43 such that the position of the base 81b is a desired position. That is, the control apparatus 4 can open and close the first opening 41 with the valve body 81a of the gate valve 80 by controlling the energization of each of the coils 43a of the planar motor 43, or the like.

Each maintenance apparatus 3 is used to replace the transfer unit 70. In one embodiment, the maintenance apparatus 3 is movable. In one embodiment, the maintenance apparatus 3 is self-propelled. In the case where the maintenance apparatus 3 is self-propelled, the maintenance apparatus 3 is implemented to be self-propelled under the control of an internal controller or an external controller. The maintenance apparatus 3 does not need to be movable. For example, the maintenance apparatus 3 may be permanently installed in the vacuum transfer module 40. Under the control of the control apparatus 4, each maintenance apparatus 3 moves to the position of the substrate processing apparatus 2 having the transfer unit 70 that requires replacement, and is connected to the vacuum transfer chamber 40a of the substrate processing apparatus 2 through the second opening 42. When the replacement of the transfer unit 70 is completed, the maintenance apparatus 3 is disconnected from the substrate processing apparatus 2 under the control of the control apparatus 4. That is, the maintenance apparatus 3 is detachably connected to the substrate processing apparatus 2. In the maintenance apparatus 3, one or more unused transfer units 70 are accommodated in a standby chamber to be described later. Further, as described later, in the maintenance apparatus 3, a planar motor similar to the planar motor 43 described above is provided in the standby chamber.

By controlling the planar motor 43 of the substrate processing apparatus 2 and the planar motor (specifically, the energization of these coils) of the maintenance apparatus 3, the control apparatus 4 can:
move the transfer unit 70 that requires the replacement from the vacuum transfer chamber 40a of the substrate processing apparatus 2 to the standby chamber of the maintenance apparatus 3; and
move the unused (that is, before used) transfer unit 70 from the standby chamber of the maintenance apparatus 3 to the vacuum transfer chamber 40a of the substrate processing apparatus 2.

Accordingly, the used transfer unit 70 in the vacuum transfer chamber 40a of the substrate processing apparatus 2 and the unused transfer unit 70 are replaced. That is, the control apparatus 4 can replace the operating transfer unit 70 located in the vacuum transfer chamber 40a with the replacement transfer unit 70 located in the standby chamber of the maintenance apparatus 3.

Details of the maintenance apparatus 3 will be described later.

The control apparatus 4 processes computer-executable instructions for causing the substrate processing apparatus 2 and the maintenance apparatus 3 to perform various types of processing to be described in the present disclosure. The control apparatus 4 may be implemented to control the respective components of the substrate processing apparatus 2 and the maintenance apparatus 3 to perform the various types of processing to be described herein below. In one embodiment, at least one of the substrate processing apparatus 2 or the maintenance apparatus 3 may partially or entirely include the control apparatus 4. The control apparatus 4 may include a processor 4a1, a storage 4a2, and a communication interface 4a3. The control apparatus 4 is implemented by, for example, a computer 4a. The processor 4a1 may read a program from the storage 4a2 and perform various control operations by executing the read program. The program may be stored in advance in the storage 4a2, or may be acquired via a medium when necessary. The acquired program is stored in the storage 4a2, read from the storage 4a2 by the processor 4a1, and executed thereby. The medium may be various recording media readable by the computer 4a, or may be a communication line connected to the communication interface 4a3. The processor 4a1 may be a central processing unit (CPU). The storage 4a2 may include a random access memory (RAM), a read only memory (ROM), a hard disk drive (HDD), a solid state drive (SSD), or a combination thereof. The communication interface 4a3 may communicate with the substrate processing apparatus 2 and the maintenance apparatus 3 via a communication line such as a local area network (LAN).

### Maintenance Apparatus 3

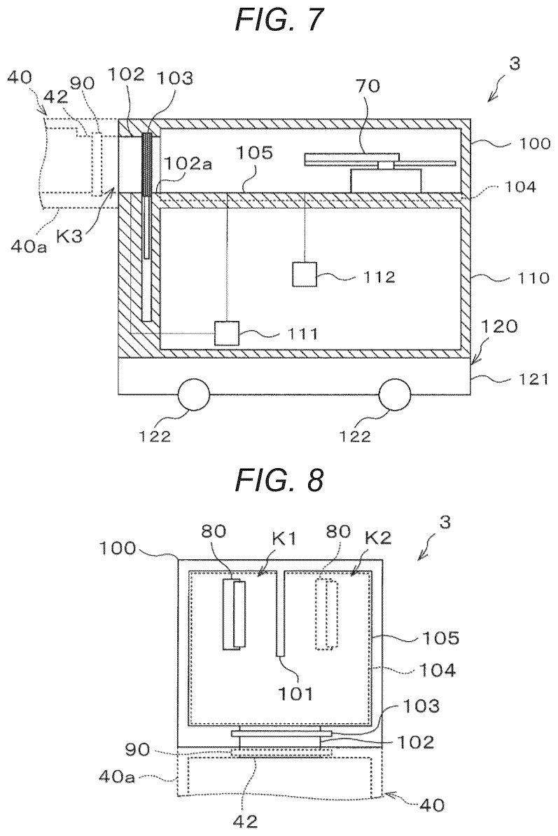

FIGS. 6 and 7 are plan views and vertical sectional views, respectively, illustrating a schematic configuration of the maintenance apparatus 3.

As illustrated in FIG. 6, the maintenance apparatus 3 includes a standby chamber 100. The standby chamber 100 is connected to the vacuum transfer chamber 40a of the vacuum transfer module 40 through the second opening 42. In the present example, the standby chamber 100 is detachably connected to the vacuum transfer chamber 40a. The standby chamber 100 accommodates an unused transfer unit 70. The standby chamber 100 may have two accommodation spaces K1 and K2 separated by a partition 101, with each accommodation space K1 and K2 capable of accommodating a used or unused transfer unit 70. In the maintenance apparatus 3, for example, the unused transfer unit 70 is accommodated in the accommodation space K1, and the used transfer unit 70 is accommodated in the accommodation space K2.

The standby chamber 100 includes an opening 102 that allows the standby chamber 100 and the vacuum transfer chamber 40a to communicate with each other through the second opening 42, and a gate valve 103 that opens and closes the opening 102.

The standby chamber 100 is provided with a planar motor 104. The planar motor 104 is a second planar motor implemented to move at least one magnetically floating movable body along the bottom surface of the standby chamber 100 serving as a second plane extending into the standby chamber 100 from the bottom surface serving as the first plane in the vacuum transfer chamber 40a. In the present example, the planar motor 104 is provided at the bottom surface of the standby chamber 100, that is, a floor surface 105, and implemented to move the transfer unit 70 along the floor surface 105. For example, similar to the planar motor 43 described above, a plurality of coils (not illustrated) are arranged in the planar motor 104. The energization of the coils of the planar motor 104 is controlled by the control apparatus 4. The control apparatus 4 controls the energization of each of the coils of the planar motor 104, so that the transfer unit 70 can be moved.

A lower wall surface 102a of a wall surface forming the opening 102 of the standby chamber 100 may have the same height as the floor surface 105 of the standby chamber 100, and the planar motor 104 may also be provided on the lower wall surface 102a forming the opening 102.

Similarly, the lower wall surface forming the second opening 42 of the vacuum transfer chamber 40a may have the same height as the floor surface of the vacuum transfer chamber 40a, and the planar motor 43 may be provided on the lower wall surface forming the second opening 42.

Further, the maintenance apparatus 3 has an apparatus chamber 110 as illustrated in FIG. 7. An exhaust mechanism 111 and a gas supply mechanism 112 are provided in the apparatus chamber 110. The exhaust mechanism 111 and the gas supply mechanism 112 are controlled by the control apparatus 4.

The exhaust mechanism 111 is connected to the standby chamber 100 and exhausts the standby chamber 100. The exhaust mechanism 111 includes, for example, a pressure adjusting valve (not illustrated) and a vacuum pump (not illustrated). The vacuum pump may include a turbo molecular pump, a roughing pump or a combination thereof. The exhaust mechanism 111 can decompress the inside of the standby chamber 100 to a predetermined vacuum level.

The exhaust mechanism 111 is connected to the opening 102. After the maintenance apparatus 3 and the vacuum transfer chamber 40a are connected to each other, the exhaust mechanism 111 exhausts a connection portion thereof. Accordingly, the connection portion can be decompressed to a predetermined vacuum level before the gate valve 103 is opened.

A protrusion for alignment may be provided on either a side surface of the vacuum transfer chamber 40a connected to the maintenance apparatus 3 or a side surface of the maintenance apparatus 3 connected to the vacuum transfer chamber 40a, and a recess into which the protrusion is fitted may be provided on the other.

At least one of a sealing member that surrounds the second opening 42 on the side surface of the vacuum transfer chamber 40a connected to the maintenance apparatus 3, and a sealing member that surrounds the opening 102 on the side surface of the maintenance apparatus 3 connected to the vacuum transfer chamber 40a may be provided. The sealing member or these sealing members can improve airtightness of the connection portion between the second opening 42 and the opening 102.

The gas supply mechanism 112 is connected to the standby chamber 100, and supplies an inert gas such as a nitrogen gas to the standby chamber 100. The gas supply mechanism 112 includes, for example, an on-off valve (not illustrated) and a flow rate adjusting valve (not illustrated). The gas supply mechanism 112 can maintain the inside of the standby chamber 100 at a pressure higher than the outside thereof. Accordingly, it is possible to prevent particles from entering the standby chamber 100.

A communication unit (not illustrated) for communicating with the transfer unit 70 and an external apparatus may be provided in the apparatus chamber 110. The communication unit is, for example, a wireless communication circuit for performing wireless communication between the transfer unit 70 and an external apparatus.

The maintenance apparatus 3 further includes a transfer mechanism 120.

The transfer mechanism 120 includes a main body 121 and wheels 122. A power supply such as a battery, a power source, a steering mechanism, and the like are provided in the main body 121. The wheels 122 are rotated by a power source in the main body 121 to move the maintenance apparatus 3 in a direction controlled by a steering mechanism in the main body 121.

### Replacing Flow of Transfer Unit 70

Next, an example of a replacing flow of the transfer unit 70 using the substrate processing system 1 will be described. The replacement of the transfer unit 70 is performed periodically, for example.

### (Step S1: Connection of Maintenance Apparatus 3)

For example, first, the control apparatus 4 connects the substrate processing apparatus 2 that includes the transfer unit 70 that requires the replacement to the maintenance apparatus 3 that accommodates the unused transfer unit 70.

Specifically, the control apparatus 4 controls the transfer mechanism 120 of the maintenance apparatus 3 to connect the vacuum transfer chamber 40a in which the transfer unit 70 that requires replacement is incorporated and in which the decompressed atmosphere (vacuum atmosphere) is maintained, and the standby chamber 100 accommodating the unused transfer unit 70. Accordingly, the second opening 42 in which the gate valve 90 is in a closed state communicates with the opening 102 in which the gate valve 103 is in the closed state.

Next, the control apparatus 4 controls the exhaust mechanism 111 to exhaust a space K3 (see FIG. 7) surrounded by the gate valves 90 and 103 in the connection portion between the second opening 42 and the opening 102, so as to obtain the decompressed atmosphere (vacuum atmosphere). When the inside of the standby chamber 100 is not in the decompressed atmosphere (vacuum atmosphere), the control apparatus 4 controls the exhaust mechanism 111 or the like to set the inside of the standby chamber 100 to the decompressed atmosphere (vacuum atmosphere).

Thereafter, the control apparatus 4 opens the gate valves 90 and 103. Accordingly, the vacuum transfer chamber 40a and the standby chamber 100 each having the decompressed atmosphere (vacuum atmosphere) communicate with each other through the second opening 42, specifically, through the second opening 42 and the opening 102.

### (Step S2: Transfer of Used Transfer Unit 70)

Next, the control apparatus 4 controls the planar motors 43 and 104 to move the used transfer unit 70 in the vacuum transfer chamber 40a into the standby chamber 100 of the maintenance apparatus 3 through the second opening 42.

Specifically, the control apparatus 4 controls the planar motor 43 to move the used transfer unit 70 in the vacuum transfer chamber 40a to the vicinity of the second opening 42.

Next, the control apparatus 4 controls the planar motors 43 and 104 to move the used transfer unit 70 in the vacuum transfer chamber 40a through the second opening 42 and the opening 102 in this order to the inside of the standby chamber 100.

Thereafter, the control apparatus 4 controls the planar motor 104 to move the used transfer unit 70 to the accommodation space K2.

### (Step S3: Transfer of Unused Transfer Unit 70)

Next, the control apparatus 4 controls the planar motors 43 and 104 to move the unused transfer unit 70 in the standby chamber 100 of the maintenance apparatus 3 into the vacuum transfer chamber 40a through the second opening 42.

Specifically, the control apparatus 4 controls the planar motor 104 to move the unused transfer unit 70 accommodated in the accommodation space K1 to the vicinity of the opening 102.

Next, the control apparatus 4 controls the planar motors 43 and 104 to move the unused transfer unit 70 in the standby chamber 100 through the opening 102 and the second opening 42 in this order to the inside of the vacuum transfer chamber 40a.

The control apparatus 4 replaces the transfer unit in the vacuum transfer chamber 40a by performing steps S2 and S3.

### (Step S4: Disconnection of Maintenance Apparatus 3)

Thereafter, the control apparatus 4 disconnects the substrate processing apparatus 2 and the maintenance apparatus 3.

Specifically, the control apparatus 4 closes the gate valves 90 and 103.

Next, the control apparatus 4 introduces a gas, such as air, into a pipe (not illustrated) communicating with the above-described space K3, and returns the space K3 to an atmospheric pressure.

Then, the control apparatus 4 controls the transfer mechanism 120 of the maintenance apparatus 3 to separate the maintenance apparatus 3 accommodating the used transfer unit 70 from the substrate processing apparatus 2 and return to a standby position.

The used transfer unit 70 in the maintenance apparatus 3 is replaced with the unused transfer unit 70, for example, by an operator after the gate valve 103 is opened at the standby position.

### Effects of Present Embodiment

In the above embodiment, the control apparatus 4 controls the planar motors 43 and 104 to move the used transfer unit 70 in the vacuum transfer chamber 40a of the substrate processing apparatus 2 to the standby chamber 100 through the second opening 42 that allows the vacuum transfer chamber 40a and the standby chamber 100 of the maintenance apparatus 3 to communicate with each other. The control apparatus 4 controls the planar motors 43 and 104 to move the unused transfer unit 70 in the standby chamber 100 to the vacuum transfer chamber 40a through the second opening 42 that allows the vacuum transfer chamber 40a and the standby chamber 100 to communicate with each other. Accordingly, the unused transfer unit 70 in the standby chamber 100 and the used transfer unit 70 in the vacuum transfer chamber 40a are replaced.

That is, in the present embodiment, the control apparatus 4 controls the planar motors 43 and 104 to replace the operating transfer unit 70 located in the vacuum transfer chamber 40a with the replacement transfer unit 70 located in the standby chamber 100.

As described above, according to the present embodiment, the magnetically floating transfer unit 70 provided in the vacuum transfer chamber 40a can be replaced as the maintenance of the vacuum transfer chamber 40a without exposing the vacuum transfer chamber 40a to the atmosphere.

In the present embodiment, a plurality of maintenance apparatuses 3 are shared among a plurality of substrate processing apparatuses 2. Therefore, it is possible to prevent an increase in cost required for the entire substrate processing system 1.

The unused transfer unit 70 and the used transfer unit 70 that are replaced may be the same type or different from each other. As the unused transfer unit 70, the transfer unit 70 with specifications suitable for the processing conditions after the replacement of the transfer unit 70 may be accommodated in the maintenance apparatus 3 and replaced with the used transfer unit 70. Accordingly, the transfer unit 70 can be replaced with an appropriate one without exposing the inside of the vacuum transfer chamber 40a to the atmosphere.

### Other Embodiments

The maintenance apparatus 3 in the above-described embodiment accommodates the unused transfer unit 70. Alternatively, as illustrated in FIG. 8, the maintenance apparatus 3 may accommodate the unused gate valve 80. By using the maintenance apparatus 3, the gate valve 80 can be replaced without exposing the vacuum transfer chamber 40a to the atmosphere.

The maintenance apparatus 3 may accommodate both the unused transfer unit 70 and the unused gate valve 80. By using the maintenance apparatus 3, the transfer unit 70 and the gate valve 80 can be replaced at the same timing without exposing the vacuum transfer chamber 40a to the atmosphere.

The unused gate valve 80 and the used gate valve 80, which are replaced by the replacement, may be the same type or different from each other. As the unused gate valve 80, a valve with specifications (for example, plasma resistance, heat resistance, corrosion resistance, and the like) suitable for processing conditions after the replacement of the gate valve 80 may be accommodated in the maintenance apparatus 3 and replaced with the used gate valve 80. Accordingly, the gate valve 80 can be replaced with an appropriate one without exposing the inside of the vacuum transfer chamber 40a to the atmosphere. Specifically, the replacement with the gate valve 80 having an appropriate type of sealing member 81c can be efficiently performed without exposing the vacuum transfer chamber 40a to the atmosphere.

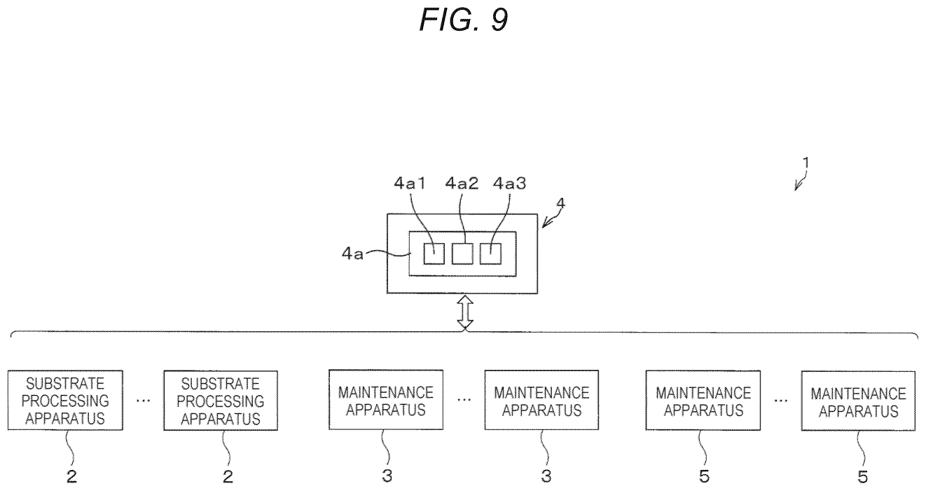

As illustrated in FIG. 9, the substrate processing system 1 may include a plurality of maintenance apparatuses 5, in addition to a plurality of maintenance apparatuses 3, and the like. The substrate processing system 1 may include the maintenance apparatus 5 instead of the maintenance apparatus 3.

Each of the maintenance apparatuses 5 is used for the maintenance of the vacuum transfer chamber 40a except for the replacement of the magnetically floating movable body. In one embodiment, the maintenance apparatus 5 is movable. In one embodiment, the maintenance apparatus 5 is self-propelled. In this case, the maintenance apparatus 5 is implemented to be self-propelled under the control of an internal or external controller. The maintenance apparatus 5 does not need to be movable. For example, the maintenance apparatus 5 may be permanently installed in the vacuum transfer module 40. Each of the maintenance apparatuses 5 moves to the position of the vacuum transfer chamber 40a of the substrate processing apparatus 2 under the control of the control apparatus 4, and is connected to the vacuum transfer chamber 40a through the second opening 42.

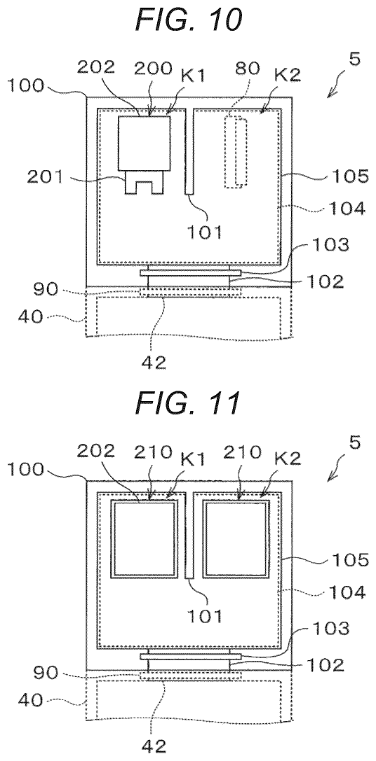

As illustrated in FIG. 10, the maintenance apparatus 5 has the same configuration as the maintenance apparatus 3. However, unlike the maintenance apparatus 3, the maintenance apparatus 5 accommodates a magnetically floating retrieval unit 200 serving as a magnetically floating maintenance unit that stands by in the standby chamber 100 in a substrate processing mode in the standby chamber 100. The number of magnetically floating retrieval units 200 (hereinafter, may be referred to as “retrieval units 200”) accommodated in the maintenance apparatus 5 is at least one.

The retrieval unit 200 is a magnetically floating movable body that moves by energizing the coils of the planar motors 43 and 104. The retrieval unit 200 is implemented to retrieve, in the maintenance mode, at least one of the transfer unit 70 and the gate valve 80 that cannot be moved in the vacuum transfer chamber 40a due to a failure to the standby chamber 100.

The retrieval unit 200 includes a pick 201 and a base 202. The pick 201 supports at least one of the transfer unit 70 and the gate valve 80. The pick 201 is connected to the base 202. Similar to the base 72c described above, a plurality of permanent magnets (not illustrated) are arranged in the base 202. The base 202 moves on the planar motors 43 and 104 by the magnetic fields generated by the coils 43a of the planar motor 43 and the coils of the planar motor 104.

With such a configuration, the control apparatus 4 can move or pivot the retrieval unit 200 by controlling, for example, the energization of each of the coils 43a of the planar motor 43 such that the position of the base 202 is a desired position. That is, the control apparatus 4 can support and move, by the pick 201, at least one of the transfer unit 70 and the gate valve 80 by controlling the energization of each of the coils 43a of the planar motor 43, or the like.

For example, the retrieval unit 200 is accommodated in the accommodation space K1, and the magnetically floating movable body (in the illustrated example, the gate valve 80) retrieved by the retrieval unit 200 is accommodated in the accommodation space K2.

The retrieval unit 200 may be provided with sensors that detect the failed transfer unit 70 and the failed gate valve 80.

The retrieval unit 200 may be common to the transfer unit 70 and the gate valve 80, or may be separately provided between the transfer unit 70 and the gate valve 80.

In the maintenance mode of the substrate processing system 1 provided with the plurality of maintenance apparatuses 5, when the transfer unit 70 is retrieved as the maintenance of the vacuum transfer chamber 40a, for example, first, the control apparatus 4 connects the substrate processing apparatus 2 that is a maintenance target and the maintenance apparatus 5.

Specifically, the control apparatus 4 performs control in the same manner as in step S1 described above.

Next, the control apparatus 4 controls the planar motors 43 and 104 to move the retrieval unit 200 that stands by in the standby chamber 100 of the maintenance apparatus 5 in the substrate processing mode to the vacuum transfer chamber 40a, and cause the retrieval unit 200 to retrieve the transfer unit 70.

Specifically, the control apparatus 4 controls the planar motor 104 to move the retrieval unit 200 accommodated in the accommodation space K1 to the vicinity of the opening 102.

Next, the control apparatus 4 controls the planar motors 43 and 104 to move the retrieval unit 200 in the standby chamber 100 through the opening 102 and the second opening 42 in this order to the inside of the vacuum transfer chamber 40a.

Thereafter, the control apparatus 4 controls the planar motor 43 to cause the pick 201 of the retrieval unit 200 to support the failed transfer unit 70.

Subsequently, the control apparatus 4 controls the planar motor 43 to move the retrieval unit 200 supporting the failed transfer unit 70 to the vicinity of the second opening 42 in the vacuum transfer chamber 40a.

Next, the control apparatus 4 controls the planar motors 43 and 104 to move the retrieval unit 200 supporting the failed transfer unit 70 from the vacuum transfer chamber 40a to the standby chamber 100 while passing the second opening 42 and the opening 102 in this order.

Thereafter, the control apparatus 4 controls the planar motor 104 to move the failed transfer unit 70 by the retrieval unit 200 and store the transfer unit 70 in the accommodation space K2.

Subsequently, the control apparatus 4 controls the planar motor 104 to return the retrieval unit 200 to the accommodation space K1.

Thereafter, the control apparatus 4 disconnects the substrate processing apparatus 2 and the maintenance apparatus 5.

Specifically, the control apparatus 4 performs control in the same manner as in step S4 described above.

The retrieval of the gate valve 80 as the maintenance of the vacuum transfer chamber 40a is performed in the same manner as the retrieval of the transfer unit 70 as the maintenance of the vacuum transfer chamber 40a.

As described above, in a mode of using the substrate processing system 1 provided with the maintenance apparatus 5, the transfer unit 70 and the gate valve 80 can be retrieved as the maintenance of the vacuum transfer chamber 40a and without exposing the vacuum transfer chamber 40a to the atmosphere. In the present embodiment as well, by using the maintenance apparatus 3, the transfer unit 70 and the gate valve 80 provided in the vacuum transfer chamber 40a can be replaced without exposing the vacuum transfer chamber 40a to the atmosphere.

Although the retrieval unit 200 is accommodated in the standby chamber 100 as the magnetically floating maintenance unit that stands by in the standby chamber 100 in the substrate processing mode in the maintenance apparatus 5 in the above-described embodiment, the magnetically floating cleaning unit 210 may be accommodated as illustrated in FIG. 11.

Similar to the retrieval unit 200, the magnetically floating cleaning unit 210 (hereinafter, may be referred to as the “cleaning unit 210”) is also a magnetically floating movable body that moves by energizing each of the coils of the planar motors 43 and 104. The cleaning unit 210 cleans the vacuum transfer chamber 40a in the maintenance mode. Specifically, the cleaning unit 210 cleans the inner wall surface of the vacuum transfer chamber 40a.

For example, the cleaning unit 210 is accommodated in each of the accommodation space K1 and the accommodation space K2.

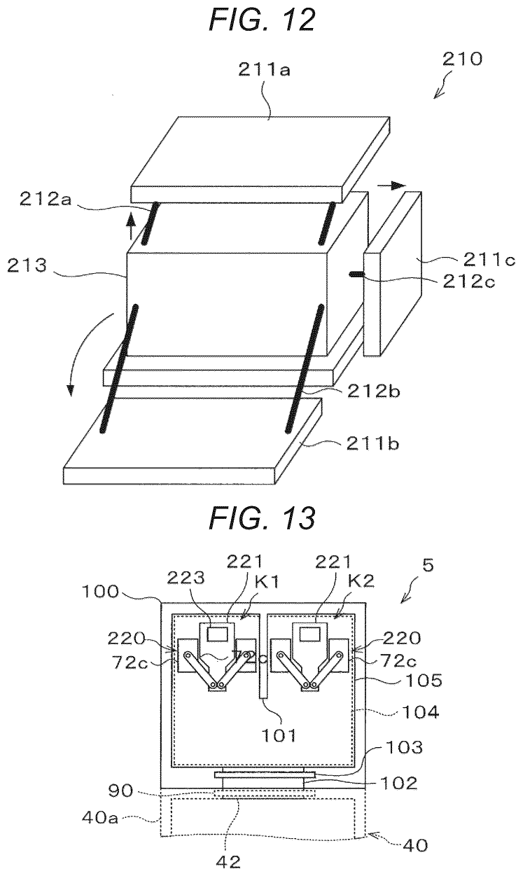

As illustrated in FIG. 12, for example, the cleaning unit 210 includes plate brushes 211a to 211c, links 212a to 212c, and a base 213. In the following description, the plate brushes 211a to 211c will be referred to as plate brushes 211 when points common to the plate brushes 211a to 211c will be described. Similarly, when illustrating points common to the links 212a to 212c, the links 212a to 212c will be referred to as links 212.

The plate brush 211a is for cleaning a ceiling surface of the vacuum transfer chamber 40a.

The plate brush 211b is for cleaning a floor surface of the vacuum transfer chamber 40a.

The plate brush 211c is for cleaning an inner wall surface formed by a vertical surface of the vacuum transfer chamber 40a.

One end portion of the link 212 is connected to the base 213.

The other end portion of the link 212a is connected to the plate brush 211a.

The other end portion of the link 212b is connected to the plate brush 211b.

The other end portion of the link 212c is connected to the plate brush 211c.

The link 212 can move the corresponding plate brush 211 between a processing position facing a cleaning target surface and a standby position closer to the base 213 than the processing position.

Similar to the base 72c described above, a plurality of permanent magnets (not illustrated) are arranged in the base 213. The base 213 moves on the planar motors 43 and 104 by the magnetic fields generated by the coils 43a of the planar motor 43 and the coils of the planar motor 104.

The base 213 may be provided with a driving unit (not illustrated) such as a motor or a cylinder that drives the movement of the plate brush 211 by the link 212. The base 213 may be provided with a communication unit (not illustrated) for communicating with the driving unit and the control apparatus 4.

With such a configuration, the control apparatus 4 can, for example, control the energization of each of the coils 43a of the planar motor 43 to swing the cleaning unit 210 parallel to a brush surface of the plate brush 211 while the plate brush 211 is in contact with a cleaning target surface. As a result, the vacuum transfer chamber 40a (specifically, an inner wall surface thereof) can be cleaned.

In a mode of using the substrate processing system 1 provided with the maintenance apparatus 5 accommodating the cleaning unit 210, the vacuum transfer chamber 40a can be cleaned as the maintenance of the vacuum transfer chamber 40a without exposing the vacuum transfer chamber 40a to the atmosphere. In the present embodiment as well, by using the maintenance apparatus 3, the transfer unit 70 and the gate valve 80 provided in the vacuum transfer chamber 40a can be replaced without exposing the vacuum transfer chamber 40a to the atmosphere.

In the method for replacing the transfer unit 70 and the gate valve 80, since a replacing work by an operator is not required, it is not necessary for the operator to access the inside of the vacuum transfer chamber 40a. Therefore, since it is not necessary to provide an opening for the access in the vacuum transfer chamber 40a, it is possible to make the inner wall surface of the vacuum transfer chamber 40a as flat as possible.

Further, in the substrate processing system 1, the transfer unit 70 that transfers the substrate W and the gate valve 80 that opens and closes the first opening 41 are magnetically floating. Accordingly, the inner wall surface of the vacuum transfer chamber 40a can be made as flat as possible.

When the inner wall surface of the vacuum transfer chamber 40a is flat, the cleaning unit 210 can easily clean the chamber 40a.

As illustrated in FIG. 13, the maintenance apparatus 5 may be accommodated in the standby chamber 100 as the magnetically floating maintenance unit that stands by in the standby chamber 100 in the substrate processing mode in the magnetically floating monitoring unit 220.

Similar to the retrieval unit 200 or the like, the magnetically floating monitoring unit 220 (hereinafter, may be referred to as a “monitoring unit 220”) is also a magnetically floating movable body that moves by energizing each of the coils of the planar motors 43 and 104. The monitoring unit 220 is implemented to monitor internal conditions of the vacuum transfer chamber 40a and the substrate processing module 60 (specifically, the substrate processing chamber 60a) in the maintenance mode.

For example, the monitoring unit 220 is accommodated in each of the accommodation space K1 and the accommodation space K2.

The monitoring unit 220 has, for example, the same configuration as that of the transfer unit 70. However, the monitoring unit 220 includes an imaging unit 221 instead of the end effector 72a.

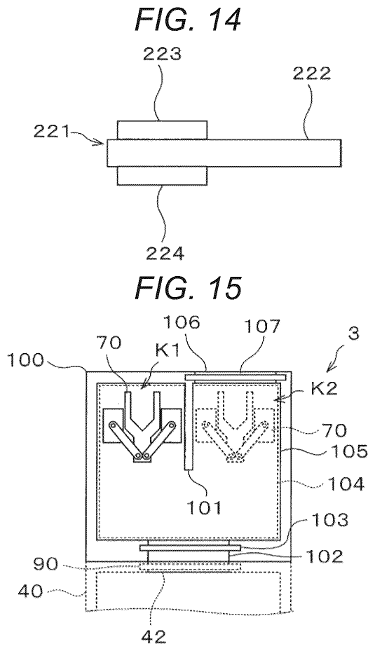

As illustrated in FIG. 14, the imaging unit 221 has a plate-shaped support member 222. An upper imaging unit 223 is provided on an upper surface of a distal end portion of the support member 222, and a lower imaging unit 224 is provided on a lower surface of the distal end portion.

Although it is not illustrated, the upper imaging unit 223 and the lower imaging unit 224 each have a transparent cover, an imaging element, and an illumination module.

The transparent cover is formed of a transparent material and defines an accommodation space of an air atmosphere. The imaging element and the illumination module are accommodated in the accommodation space of the air atmosphere.

The imaging element of the upper imaging unit 223 is provided to capture an image above the upper imaging unit 223, and the imaging element of the lower imaging unit 224 is provided to capture an image below the lower imaging unit 224.

The illumination module illuminates at least an imaging range of the imaging element.

The support member 222 may be provided with a storage that stores imaging results obtained by the upper imaging unit 223 and the lower imaging unit 224. The support member 222 may be provided with a communication unit (not illustrated) for wirelessly communicating the imaging results by the upper imaging unit 223 and the lower imaging unit 224 to the control apparatus 4.

By, for example, controlling the energization of each of the coils 43a of the planar motor 43, the control apparatus 4 can position the upper imaging unit 223 and the lower imaging unit 224 of the monitoring unit 220 in the vacuum transfer chamber 40a or the substrate processing chamber 60a. Accordingly, the upper imaging unit 223 and the lower imaging unit 224 of the monitoring unit 220 can monitor the internal conditions of the vacuum transfer chamber 40a and the substrate processing chamber 60a, and specifically, can capture an image of the inside of the vacuum transfer chamber 40a and the substrate processing chamber 60a.

In a mode of using the substrate processing system 1 provided with the maintenance apparatus 5 accommodating the monitoring unit 220, the internal conditions of the vacuum transfer chamber 40a and the substrate processing chamber 60a as the maintenance of the vacuum transfer chamber 40a can be monitored without exposing the vacuum transfer chamber 40a to the atmosphere. For example, the internal conditions of the substrate processing chamber 60a are monitored when an abnormal discharge occurs in the substrate processing chamber 60a. In this case, an abnormal discharge location in the substrate processing chamber 60a can be identified based on a monitoring result obtained by the monitoring unit 220.

In the present embodiment as well, by using the maintenance apparatus 3, the transfer unit 70 and the gate valve 80 provided in the vacuum transfer chamber 40a can be replaced without exposing the vacuum transfer chamber 40a to the atmosphere.

### Modification Examples

In the above-described embodiment, the maintenance apparatus 3 is detachably connected to the substrate processing apparatus 2, and connected to the substrate processing apparatus 2 only when the transfer unit 70 and the gate valve 80 are replaced. However, the maintenance apparatus 3 may be connected to the substrate processing apparatus 2 at times other than the replacement. That is, the maintenance apparatus 3 may be permanently installed for the substrate processing apparatus 2 as described above. The same applies to the maintenance apparatus 5.

When the maintenance apparatus 3 is permanently installed to the substrate processing apparatus 2, as illustrated in FIG. 15, an opening 106 for communicating the standby chamber 100 and the outside of the maintenance apparatus 3 and a gate valve 107 for opening and closing the opening 106 may be provided, for example, on a side (hereinafter, referred to as a back side) opposite to the opening 102 side (hereinafter, referred to as a front side).

Accordingly, the operator can replace the transfer unit 70 and the gate valve 80 in the standby chamber 100 in a state in which the maintenance apparatus 3 is connected to the substrate processing apparatus 2. Specifically, the operator can take out the used transfer unit 70 and the gate valve 80 from the standby chamber 100 through the opening 106, and replenish the unused transfer unit 70 and the gate valve 80 into the standby chamber 100 through the opening 106.

Even when the maintenance apparatus 3 is not permanently installed to the substrate processing apparatus 2, the opening 106 and the gate valve 107 may be provided on the back side of the maintenance apparatus 3.

When the opening 106 and the gate valve 107 are provided on the back side of the maintenance apparatus 3, the transfer unit 70 and the gate valve 80 in the standby chamber 100 may be replaced as follows. That is, first, in a state in which one maintenance apparatus 3 (hereinafter, referred to as one apparatus 3) is connected to the substrate processing apparatus 2, the control apparatus 4 connects another maintenance apparatus 3 (hereinafter, referred to as another apparatus 3) to the back side of the one apparatus 3. Accordingly, the standby chamber 100 of the one apparatus 3 communicates with the standby chamber 100 of the other apparatus 3 through the opening 106 on the back side of the one apparatus 3 and the opening 102 on the front side of the other apparatus 3. Then, the control apparatus 4 controls the energization of the coils of the planar motor 104 of one apparatus 3 and the other apparatus 3, and moves the used transfer unit 70 and the gate valve 80 from the standby chamber 100 of the one apparatus 3 to the standby chamber 100 of the other apparatus 3 through the openings 102 and 106, that is, takes out the same. The control apparatus 4 controls the energization of the coils of the planar motor 104 of the one apparatus 3 and the other apparatus 3, and moves the transfer unit 70 and the gate valve 80 from the standby chamber 100 of the other apparatus 3 to the standby chamber 100 of the one apparatus 3 through the openings 102 and 106. In this way, the transfer unit 70 and the gate valve 80 in the standby chamber 100 may be replaced.

Similar to the maintenance apparatus 3 described above, the opening 106 and the gate valve 107 may be provided on the back side of the maintenance apparatus 5. Accordingly, the transfer unit 70 and the gate valve 80 retrieved by the retrieval unit 200, the retrieval unit 200 itself, the cleaning unit 210, and the monitoring unit 220 can be taken out from the standby chamber 100 of the maintenance apparatus 5 connected to the substrate processing apparatus 2 through the opening 106. The take-out is performed, for example, in the same manner as the take-out of the transfer unit 70 and the gate valve 80 in the standby chamber 100 in the maintenance apparatus 3 described above.

In the above-described embodiment, the standby chamber 100 of the maintenance apparatus 3 and the vacuum transfer chamber 40a communicate with each other through the second opening 42, which is an opening different from the first opening 41 through which the substrate processing chamber 60a and the vacuum transfer chamber 40a communicate with each other. Alternatively, the standby chamber 100 of the maintenance apparatus 3 and the vacuum transfer chamber 40a may communicate with each other through the first opening 41. That is, the maintenance apparatus 3 may be connected to a portion of the vacuum transfer chamber 40a to which the substrate processing chamber 60a is connected. The same applies to the maintenance apparatus 5.

The maintenance apparatus 3 and the maintenance apparatus 5 may be integrated, and both the magnetically floating movable body (i.e., retrieval unit 200) for replacement and the magnetically floating maintenance unit (i.e., the maintenance apparatus 5) may be accommodated in one apparatus.

One of the magnetically floating maintenance units accommodated in the maintenance apparatus 5 may have two or more functions among the retrieval unit 200, the cleaning unit 210, and the monitoring unit 220.

Further, an imaging unit corresponding to the upper imaging unit 223 and the lower imaging unit 224 of the monitoring unit 220 may be provided in the transfer unit 70 accommodated in the maintenance apparatus 3, and the internal conditions of the vacuum transfer chamber 40a and the substrate processing chamber 60a may be monitored by the imaging unit.

It shall be understood that the embodiments disclosed herein are illustrative and are not restrictive in all aspects. The embodiment described above may be omitted, replaced, or modified in various forms without departing from the scope and spirit of the appended claims. For example, the components of the embodiments described above may be combined as desired. From the desired combination, functions and effects of each component related to the combination can be obtained as a matter of course, and other functions and effects apparent to those skilled in the art can be obtained from the description herein.

The effects described herein are merely illustrative or exemplary, and are not limited. In other words, the technique according to the present disclosure may have other effects apparent to those skilled in the art from the description herein, in addition to or in place of the effects described above. The present disclosure encompasses various modifications to each of the examples and embodiments discussed herein. According to the disclosure, one or more features described above in one embodiment or example can be equally applied to another embodiment or example described above. The features of one or more embodiments or examples described above can be combined into each of the embodiments or examples described above. Any full or partial combination of one or more embodiment or examples of the disclosure is also part of the disclosure.

1. A substrate processing system comprising:
a substrate processing apparatus;
a maintenance apparatus; and
control circuitry, wherein
the substrate processing apparatus includes
a substrate processing module including a substrate processing chamber, and
a vacuum transfer module,
the vacuum transfer module includes:
a vacuum transfer chamber having a first opening and a second opening, the vacuum transfer chamber being connected to the substrate processing module through the first opening, and
a first planar motor configured to move at least one magnetically floating movable body along a first plane in the vacuum transfer chamber,
the maintenance apparatus includes:
a standby chamber connected to the vacuum transfer chamber through the second opening, and
a second planar motor configured to move the at least one magnetically floating movable body along a second plane extending from the first plane into the standby chamber, and
the control circuitry is configured to control the first planar motor and the second planar motor to replace an operating magnetically floating movable body of the at least one magnetically floating movable body located in the vacuum transfer chamber with a replacement magnetically floating movable body of the at least one magnetically floating movable body located in the standby chamber.

2. The substrate processing system according to claim 1, wherein
the at least one magnetically floating movable body includes a magnetically floating substrate transferer configured to transfer a substrate within the vacuum transfer chamber.

3. The substrate processing system according to claim 1, wherein
the at least one magnetically floating movable body includes a magnetically floating gate valve configured to open and close the first opening.

4. The substrate processing system according to claim 1, wherein
the at least one magnetically floating movable body includes at least one magnetically floating maintenance unit that stands by in the standby chamber in a substrate processing mode, and
the at least one magnetically floating maintenance unit includes at least one of a pick and a base.

5. The substrate processing system according to claim 4, wherein
the at least one magnetically floating maintenance unit includes a magnetically floating cleaning unit configured to clean the vacuum transfer chamber, and
the magnetically floating cleaning unit includes:
a base; and
plate brushes connected to the base of the magnetically floating cleaning unit.

6. The substrate processing system according to claim 4, wherein
the at least one magnetically floating maintenance unit further includes a magnetically floating retrieval unit configured to retrieve a movable body in the vacuum transfer chamber to the standby chamber, and
the magnetically floating retrieval unit includes the pick and the base.

7. The substrate processing system according to claim 4, wherein
the at least one magnetically floating maintenance unit includes a magnetically floating monitoring unit configured to monitor an internal condition of the vacuum transfer chamber and the substrate processing module, and
the magnetically floating monitoring unit includes an imager having a plate-shaped support member.

8. The substrate processing system according to claim 1, wherein
the maintenance apparatus is movable, and the standby chamber is detachably connected to the vacuum transfer chamber.

9. A substrate processing system comprising:
a substrate processing apparatus;
a maintenance apparatus; and
control circuitry, wherein
the substrate processing apparatus includes
a substrate processing module including a substrate processing chamber, and
a vacuum transfer module,
the vacuum transfer module includes
a vacuum transfer chamber having a first opening and a second opening, the vacuum transfer chamber being connected to the substrate processing module through the first opening, and
a first planar motor configured to move at least one magnetically floating movable body along a first plane in the vacuum transfer chamber,
the maintenance apparatus includes
a standby chamber connected to the vacuum transfer chamber through the second opening, and
a second planar motor configured to move the at least one magnetically floating movable body along a second plane extending from the first plane into the standby chamber,
the at least one magnetically floating movable body includes at least one magnetically floating maintenance unit standing by in the standby chamber in a substrate processing mode, the at least one magnetically floating maintenance unit including at least one of a pick and a base, and
the control circuitry is configured to control the first planar motor and the second planar motor in a maintenance mode to move the at least one magnetically floating maintenance unit from the standby chamber to the vacuum transfer chamber.

10. The substrate processing system according to claim 9, wherein
the at least one magnetically floating maintenance unit includes a magnetically floating cleaning unit configured to clean the vacuum transfer chamber, and
the magnetically floating cleaning unit includes:
a base; and
plate brushes connected to the base of the magnetically floating cleaning unit.

11. The substrate processing system according to claim 9, wherein
the at least one magnetically floating maintenance unit further includes a magnetically floating retrieval unit configured to retrieve a movable body in the vacuum transfer chamber to the standby chamber, and
the magnetically floating retrieval unit includes the pick and the base.

12. The substrate processing system according to claim 11, wherein
the magnetically floating retrieval unit includes a plurality of permanent magnets arranged in the base.

13. The substrate processing system according to claim 9, wherein
the at least one magnetically floating maintenance unit includes a magnetically floating monitoring unit configured to monitor an internal condition of the vacuum transfer chamber and the substrate processing module, and
the magnetically floating monitoring unit includes an imager having a plate-shaped support member.

14. The substrate processing system according to claim 9, wherein
the maintenance apparatus is movable, and the standby chamber is detachably connected to the vacuum transfer chamber.

15. The substrate processing system according to claim 9, wherein
the at least one magnetically floating maintenance unit includes the pick attached to the base.

16. A movable maintenance apparatus comprising:
a standby chamber detachably connected to a vacuum transfer chamber; and
a planar motor configured to move at least one magnetically floating movable body along a first plane in the standby chamber, the first plane extending from a second plane in the vacuum transfer chamber when the standby chamber is connected to the vacuum transfer chamber.

17. The movable maintenance apparatus according to claim 16, wherein
the at least one magnetically floating movable body includes at least one magnetically floating maintenance unit standing by in the standby chamber in a substrate processing mode, and
the at least one magnetically floating maintenance unit includes at least one of a pick and a base.

18. The movable maintenance apparatus according to claim 17, wherein
the at least one magnetically floating maintenance unit includes a magnetically floating cleaning unit configured to clean the vacuum transfer chamber in a maintenance mode, and
the magnetically floating cleaning unit includes:
a base; and
plate brushes connected to the base of the magnetically floating cleaning unit.

19. The movable maintenance apparatus according to claim 17, wherein
the at least one magnetically floating maintenance unit further includes a magnetically floating retrieval unit configured to retrieve a movable body in the vacuum transfer chamber to the standby chamber in a maintenance mode, and
the magnetically floating retrieval unit includes the pick and the base.

20. The movable maintenance apparatus according to claim 17, wherein
the at least one magnetically floating maintenance unit includes a magnetically floating monitoring unit configured to monitor an internal condition of the vacuum transfer chamber and a substrate processing module in a maintenance mode, and
the magnetically floating monitoring unit includes an imager having a plate-shaped support member.
